(19) United States
(12) Patent Application Publication
(10) Pub. No.: US 2017/0162827 A1
(43) Pub. Date: Jun. 8, 2017

(54) SUBSTRATE STRUCTURE

(71) Applicant: Industrial Technology Research Institute, Hsinchu (TW)

(72) Inventors: Hsiao-Fen Wei, New Taipei City (TW); Liang-You Jiang, New Taipei City (TW)

(73) Assignee: Industrial Technology Research Institute, Hsinchu (TW)

(21) Appl. No.: 15/437,454

(22) Filed: Feb. 21, 2017

Related U.S. Application Data
(63) Continuation of application No. 14/279,327, filed on May 16, 2014.
(60) Provisional application No. 61/834,431, filed on Jun. 13, 2013.

(30) Foreign Application Priority Data
Mar. 7, 2014 (TW) 103107958

(51) Int. Cl. H01L 51/52; H01L 51/00

(52) U.S. Cl. CPC H01L 51/5256; H01L 51/524; H01L 51/5246; H01L 51/0097

(57) ABSTRACT

A substrate structure including a bottom organic layer, at least one inorganic layer, at least one organic layer and at least one protruding object is provided. The at least one protruding object is protruded from an upper surface of the bottom organic layer or the organic layer. A maximum height of the protruding object protruded from the upper surface of the bottom organic layer or the organic layer is H, and a thickness of the organic layer covering the protruding object is T, wherein T≧1.1H.

### CROSS-REFERENCE TO RELATED APPLICATION

This application is a continuation of and claims the priority benefit of a prior application Ser. No. 14/279,327, filed on May 16, 2014, now pending. This prior application Ser. No. 14/279,327 claims the priority benefits of U.S. provisional application Ser. No. 61/834,431, filed on Jun. 13, 2013 and Taiwan application serial no. 103107958, filed on Mar. 7, 2014. The entirety of each of the above-mentioned patent applications is hereby incorporated by reference herein and made a part of this specification.

### BACKGROUND

### Technical Field

The disclosure relates to a substrate structure.

### Description of Related Art

The flexible substrates are flexible, portable, safe, and broad in product applications. However, the flexible substrates are poor resistance to high temperature and poor resistance to moisture and oxygen. Since the typical flexible substrate fails to resist permeation of moisture and oxygen, electronic devices on the substrate are rapidly deteriorated so that the devices fabricated have short lifespan and cannot satisfy market demands. It has become one of important issues for developers to effectively improve characteristics of the flexible substrate in resisting the permeation of moisture and oxygen for improving a reliability of the electronic device.

### SUMMARY

A substrate structure is provided according to an embodiment of the disclosure, which includes a bottom organic layer, a plurality of inorganic layers comprising a bottom inorganic layer and an upper inorganic layer; at least one organic layer disposed between the bottom inorganic layer and the upper inorganic layer; and a protruding object protruded from an upper surface of the bottom organic layer. The bottom inorganic layer conformally covers the protruding object. A maximum height of the protruding object protruded from the upper surface of the bottom organic layer is H, and a distance measured from the bottom inorganic layer at the maximum height of the protruding object to a bottom of the upper inorganic layer is ≧0.1 H.

In order to the make aforementioned and other features and advantages of the present disclosure comprehensible, embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A to FIG. 1D are schematic views illustrating a fabricating process of a substrate structure according to the first embodiment of the disclosure.

FIG. 2A is a cross-sectional view of a substrate structure according to the second embodiment of the disclosure.

FIG. 2B is a cross-sectional view of a substrate structure according to the third embodiment of the disclosure.

FIG. 3A is a top view of a substrate structure according to the fourth embodiment of the disclosure.

FIG. 3B is a cross-sectional view along line I-I′ in FIG. 3A.

FIG. 4 is a cross-sectional view of a substrate structure according to the fifth embodiment of the disclosure.

FIG. 5 is a cross-sectional view of a substrate structure according to the sixth embodiment of the disclosure.

FIG. 6 is a cross-sectional view of a substrate structure according to the seventh embodiment of the disclosure.

FIG. 7 is a cross-sectional view of a substrate structure according to the eighth embodiment of the disclosure.

FIG. 8 is a cross-sectional view of a substrate structure according to the ninth embodiment of the disclosure.

FIG. 9 is a cross-sectional view of the spacer composed of an organic material.

FIG. 10 is a cross-sectional view of a substrate structure according to the tenth embodiment of the disclosure.

FIG. 11 is a cross-sectional view of a substrate structure according to the eleventh embodiment of the disclosure.

FIG. 12 is a cross-sectional view of a substrate structure according to the twelfth embodiment of the disclosure.

FIG. 13 is a cross-sectional view of a substrate structure according to the thirteenth embodiment of the disclosure.

FIG. 14 is a cross-sectional view of a package structure according to an embodiment of the disclosure.

FIG. 15A is a cross-sectional view of a first substrate disposed with a bottom-emitting organic light emitting device.

FIG. 15B is a cross-sectional view of a first substrate disposed with a top-emitting organic light emitting device.

FIG. 16 to FIG. 19 are cross-sectional views of package structures according to other embodiments of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

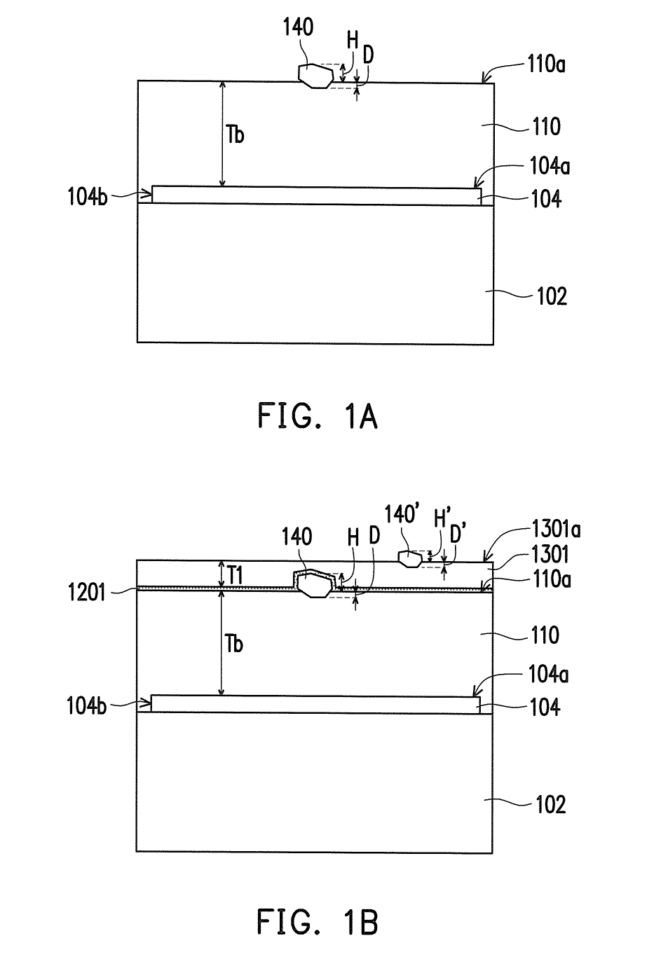

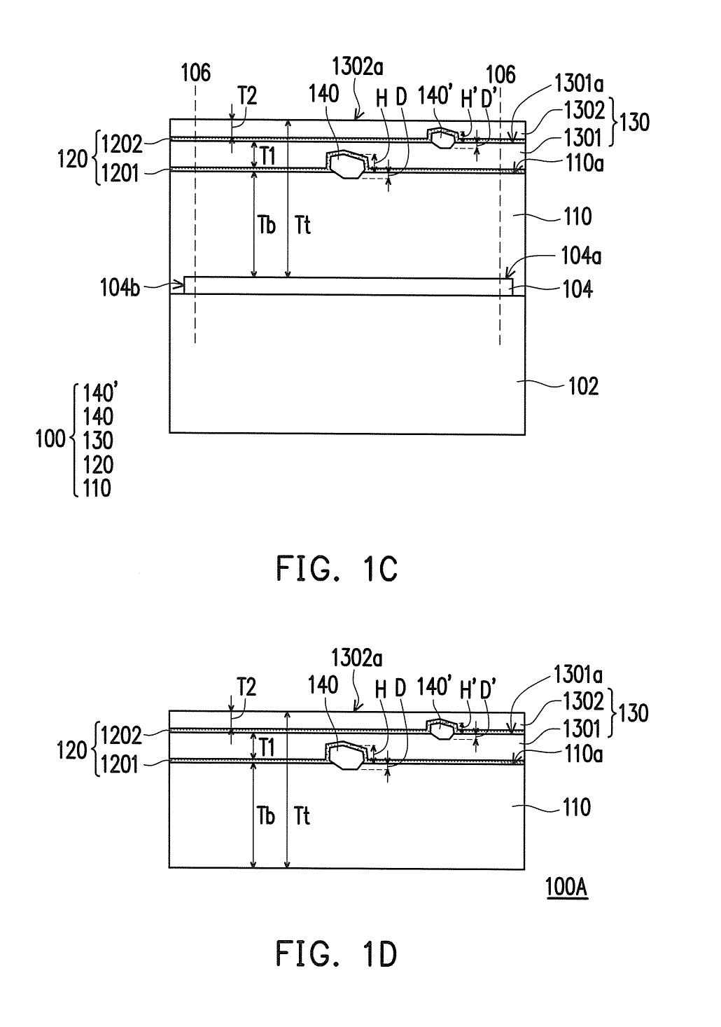

FIG. 1A to FIG. 1D are schematic views illustrating a fabricating process of a substrate structure according to the first embodiment of the disclosure.

Referring to FIG. 1A, first, a releasable region part 104 is formed on a carrier 102. A method of forming the releasable region part 104 includes, for example, performing a surface treatment on the releasable region part of the carrier 102 to reduce adhesive strength of a bottom organic layer 110 with respect to the carrier 102, forming a thin film having poorer adhesive strength with respect to the bottom organic layer 110, or forming a thin film having good adhesive strength with respect to the bottom organic layer 100 but poor adhesive strength with respect to the carrier 102. A material of the releasable region part 104 is, for example, parylene series material, or polytetrafluoroethene (PTFE) series material, or a siloxane series material. The bottom organic layer 110 is formed on the releasable region part 104, wherein the bottom organic layer 110 covers an upper surface 104a and a sidewall 104b of the releasable region part 104, and an area of bottom organic layer 110 may be greater than an area of the releasable region part 104. A method of forming the bottom organic layer 110 includes, for example, forming an organic material layer (not illustrated) by a wet coating, followed by curing (drying) the organic material layer by heating, irradiation or other suitable methods, so as to form the bottom organic layer 110. A material of the bottom organic layer 110 includes polyimide (PI), polycarbonate (PC), polyethersulfone (PES), polynorbornene (PNB), polyetherimide (PEI), polyethylene terephthalate (PEN), polyethylene terephthalate (PET), polymethylmethacrylate (PMMA), and other suitable organic materials. Furthermore, a thickness of the bottom organic layer 110 is Tb.

In the present embodiment, after the bottom organic layer 110 is formed, a washing process may be performed to clean the upper surface of the formed organic layer before proceeding to fabrication of a next layer, though such washing process is not a necessary step. However, substances or particles on the upper surface may not be completely removed during the washing process, and a protruding object 140 is composed of said unremoved residues on the bottom organic layer 110. During the process of forming the bottom organic layer 110 or after the bottom organic layer 110 is formed, it is possible that at least one protruding object 140 may exist on the upper surface 110a of the bottom organic layer 110. Therein, a part of the protruding object 140 may be embedded in the bottom organic layer 110, or attached on the upper surface 110a of the bottom organic layer 110 due to adhesion or electrostatic attraction. Generally, the protruding object 140 is, for example, particles in a coating solution, particles in a coating equipment, particles in a curing equipment or particles in other environments. Therein, the particles in the coating solution may be substances or impurities which are undissolved in the coating solution. In other words, a material of the protruding object 140 may be identical to that of the bottom organic layer 110, and may also be different from that of the bottom organic layer 110.

In the present embodiment, a maximum height of the protruding object 140 protruded from the upper surface 110a of the bottom organic layer 110 is H, and a maximum depth of the protruding object 140 embedded in the bottom organic layer 110 is D, wherein D≧(1/4)(H+D), for example. In case the maximum depth D of the particles embedded in the bottom organic layer 110 is greater than or equal to a quarter (1/4) of a total height (H+D) of the particles, said particles with relation of D≧(1/4)(H+D) are less likely to be removed during the washing process thereby composing the protruding object 140. In addition, as a standard of a common clean room, a maximum particle size of the protruding object 140 is approximately 5 μm.

Referring to FIG. 1B, for example, a first inorganic layer 1201 may be conformally formed on the bottom organic layer 110, wherein the first inorganic layer 1201 covers the upper surface 110a of the bottom organic layer 110, and a partial surface of the protruding object 140 protruded from the upper surface 110a. A method of forming the first inorganic layer 1201 includes, for example, a chemical vapor deposition, a sputtering, an atomic layer deposition, a liquid coating or other suitable methods. A material of the first inorganic layer 1201 is, for example, silicon oxide, silicon nitride, silicon oxynitride, aluminum oxide, aluminum or other suitable inorganic gas barrier materials. Next, a first organic layer 1301 is formed on the first inorganic layer 1201, wherein the first organic layer 1301 covers the first inorganic layer 1201 and the protruding object 140. A method of forming the first organic layer 1301 includes, for example, forming a first organic material layer (not illustrated) by a wet coating, followed by curing the first organic material layer by heating, irradiation or other suitable methods, so as to forms the first organic layer 1301. The method of forming the first organic layer 1301 may also include, for example, depositing a thin film on the first inorganic layer 1201 by utilizing a vacuum deposition. A material of the first organic layer 1301 includes polyimide (PI), polycarbonate (PC), polyethersulfone (PES), polynorbornene (PNB), polyetherimide (PEI), polyethylene terephthalate (PEN), polyethylene terephthalate (PET), polymethylmethacrylate (PMMA), polytetrafluoroethene (PTFE), parylene series material, perfluorinated chemicals (PFCs), or other suitable organic materials.

In the present embodiment, a thickness of the first organic layer 1301 is T1, wherein T1≧1.1 H. Therein, a method of deciding the thickness T1 includes, for example, measuring a surface relief of the upper surface 110a of the bottom organic layer 110 (i.e., measuring the maximum height H of the protruding object 140 protruded from the upper surface 110a of the bottom organic layer 110), followed by deciding a value of the thickness T1 that satisfies T1≧1.1 H. Generally, the height H of the protruding object 140 disposed on the bottom organic layer 110 is not greater than the thickness Tb of the bottom organic layer 110, and the thickness T1 of the first organic layer 1301 may be less than that of a previous organic layer (ex. the bottom organic layer 110), so as to reduce a relief difference caused by the protruding object 140. In other embodiments, the step of measuring the surface relief may also be omitted, and the thickness T1 of the first organic layer 1301 may be decided by using the thickness Tb of the bottom organic layer 110 instead (i.e., Tb≧T1).

In the present embodiment, after the first organic layer 1301 is formed, a protruding object 104′ composed of unremoved residues may exist. A material of the protruding object 140′ may be identical to that of the first organic layer 1301, and may also be different from that of the first organic layer 1301. Further, in the present embodiment, a maximum height of the protruding object 140′ protruded from an upper surface 1301a of the first organic layer 1301 is H′, and a maximum depth of the protruding object 140′ embedded in the first organic layer 1301 is D′, wherein D′≧(1/4)(H′+D′), for example. Moreover, in an embodiment, the thickness of the organic layer may have influence on a size of the protruding object. Larger residues on a thin organic layer may be easily removed. Therefore, as compared to a thick organic layer, the protruding object on the thin organic layer may be smaller in size and lesser in quantity. Herein, the thickness T1 of the first organic layer 1301 may be less than the thickness Tb of the bottom organic layer 110, and a size of the protruding object 140′ may be less than a size of the protruding object 140 (i.e., (H+D)>(H′+D′)).

Referring to FIG. 1C, for example, a second inorganic layer 1202 may be formed on the first organic layer 1301, wherein the second inorganic layer 1202 covers the upper surface 1301a of the first organic layer 1301 and a partial surface of the protruding object 140′ protruded from the upper surface 1301a. A method of forming the second inorganic layer 1202 includes, for example, a chemical vapor deposition, a sputtering, an atomic layer deposition, a liquid coating or other suitable methods. A material of the second inorganic layer 1202 is, for example, silicon oxide, silicon nitride, silicon oxynitride, aluminum oxide, aluminum or other suitable inorganic gas barrier materials. Next, a second organic layer 1302 is formed on the second inorganic layer 1202, wherein the second organic layer 1302 covers the second inorganic layer 1202 and the protruding object 140′. A method of forming the second organic layer 1302 includes, for example, forming a second organic material layer (not illustrated) by a wet coating, followed by curing the second organic material layer by heating, irradiation or other suitable methods, so as to form the second organic layer 1302. The method of forming the second organic layer 1302 may also include, for example, depositing a thin film on the second inorganic layer 1202 by utilizing a vacuum deposition. A material of the second organic layer 1302 includes polyimide (PI), polycarbonate (PC), polyethersulfone (PES), polynorbornene (PNB), polyetherimide (PEI), polyethylene terephthalate (PEN), polyethylene terephthalate (PET), polymethylmethacrylate (PMMA), polytetrafluoroethene (PTFE), parylene series material, perfluorinated chemicals (PFCs), or other suitable organic materials. In an embodiment, a material of the bottom organic layer 110 may be identical to a material of at least one of the first organic layer 1301 and the second organic layer 1302.

In the present embodiment, a thickness of the second organic layer 1302 is T2, wherein T2≧1.1 H′. In the case the first organic layer 1301 has smooth the relief difference caused by the protruding object 140, thickness T2 of the second organic layer 1302 may also be set to T1≧T2. After the second organic layer 1302 is formed, an upper surface of the second organic layer 1302 may be cleaned and smoothed by washing the upper surface of said organic layer. In an embodiment, larger residues on a thin organic layer may be easily removed. Therefore, as compared to a thick organic layer, the protruding object on the thin organic layer may be smaller in size and lesser in quantity. In the present embodiment, the thickness T2 of the second organic layer 1302 farther from the bottom organic layer 110 is less than the thickness T1 of the first organic layer 1301 more adjacent to the bottom organic layer 110, and an upper surface 1302a of the second organic layer 1302 is smoother than that of the first organic layer 1301.

In the present embodiment, a plurality of inorganic layers (including the first inorganic layer 1201 and the second inorganic layer 1202) and a plurality of organic layers 130 (including the first organic layer 1301 and the second organic layer 1302) are alternately stacked on the bottom organic layer 110. That is, the first inorganic layer 1201, the first organic layer 1301, the second inorganic layer 1202 and the second organic layer 1302 are stacked on the bottom organic layer 110 to compose a substrate structure 100. A total thickness Tt of the substrate structure 100 is a total of thicknesses of the inorganic layers 120 and thicknesses of the organic layers 130, and the total thickness Tt may be, for example, 5 μm to 50 μm. Further, although the present embodiment is illustrated by using two inorganic layers 120 and two organic layers 130 being alternately stacked as an example, the disclosure is not limited thereto. In other embodiments, it may also include at least one of the inorganic layers 120 and at least one of the organic layers 130 being alternately stacked.

Referring back to FIG. 1C, the organic layers 130, the inorganic layers 120, the bottom organic layer 110 and the releasable region part 104 are cut along a cut line 106, so that the substrate structure 100 formed by stacking the organic layers 130, the inorganic layers 120 and the bottom organic layer 110 may be separated from the carrier 102 through the releasable region part 104. A method of cutting includes, for example, a laser cutting, a saw cutting or other suitable cutting process.

Referring to FIG. 1D, as described above, a separated substrate structure 100A is thereby completed. In the substrate structure 100A, on a direction from where adjacent to the bottom organic layer 110 to where far from the bottom organic layer 110, the thicknesses of the organic layers 130 may be gradually reduced, so that an upper surface (i.e., the surface 1302a) of the substrate structure 100 may be smoother, but the disclosure is not limited thereto. In other embodiments, T1 may also be equal to or less than T2 (T1=T2 or T1<T2) as long as the upper surface of the substrate structure 100 is smooth. In the present embodiment, the thickness of each organic layer 130 is capable of covering and smoothing the protruding object on the previous organic layer, and the thickness of each organic layer 130 is, for example, 0.1 to 10 μm. For instance, in the case T1≧1.1 H, the thickness T1 of the first organic layer 1301 may cover and smooth the protruding object 140 on the upper surface 110a of the bottom organic layer 110.

In addition, on the direction from where adjacent to the bottom organic layer 110 to where far from the bottom organic layer 110, when the thicknesses of the organic layers 130 are gradually reduced, demands for a gas barrier capability in the inorganic layers 120 may also be reduced. Therein, the inorganic layer 120 far from the bottom organic layer 110 is mainly used to avoid moisture and oxygen lateral permeating to the previous organic layer 130, and amounts of moisture and oxygen may be less once the organic layers got thinner, so as to lower a difficulty in fabricating process. In other words, a condition in the fabricating process of the inorganic layers 120 may be adjusted depending on different demands. For example, when demands for the gas barrier capability in the inorganic layers 120 is relatively low, the inorganic layers 120 may be fabricated by adopting a fabricating process with lower temperature or shorter time.

A water vapor transmission rate (WVTR) of the substrate structure 100A at 60° C. is, for example, less than 0.001 g/m² day, and more preferably to be 10-⁶ g/m² day. In the present embodiment, the water vapor transmission rate of the substrate structure 100A is decided depending on a gas barrier performance (or quality) of the inorganic layers 120. Nevertheless, the gas barrier performance of the inorganic layers 120 is under influences of the organic layer 130, such as smoothness of the upper surface or better temperature resistance of the material of the organic layers 130. Under circumstances where the total thickness Tt of the substrate structure 100A remaining unchanged (so as to maintain mechanical strength), an optimized design may be made by the thicknesses of the organic layers 130 in an embodiment of the disclosure, such that the substrate structure 100A may provide a smoother upper surface (the upper surface 1302a), and a gas barrier characteristic and a flexibility characteristic are more preferable.

In the present embodiment, a material of at least one of the bottom organic layer 110 or the organic layer 130 may be, for example, a high temperature material, in which 5% weight loss temperature may be greater than 400° C., and an amount of an outgas at 400° C. may be less than 50 ng/cm², preferably to be less than 20 ng/cm², and more preferably to be less than 6 ng/cm². In the present embodiment, because the organic layers 130 adopt a material having more preferable resistance to high temperature, the outgas or gaseous decomposition caused by the organic layers 130 due to poor resistance to high temperature may be avoided during a high temperature process of forming the inorganic layers 120, so as to prevent bubbles from being formed in the organic layers to affect the quality of the inorganic layers 120. In other words, the organic layers 130 with high temperature resistance may include the smoother upper surface (since the bubbles are not formed) to solve problems including non-uniform thickness, uneven surface and discontinuous film (such as disconnection) of the inorganic layers 120 formed thereon, such that the substrate structure 100A may provide the gas barrier characteristic and the flexibility characteristic being more preferable. During a process of performing a high temperature curing (drying) to the organic layers 130 with resistance to high temperature, an annealing treatment may be performed to the inorganic layers 120 while heating the organic layers 130, so that a structure of the inorganic layers 120 may be more compact. The gas bather characteristic and the flexibility characteristic may be further improved while simplifying the fabricating process.

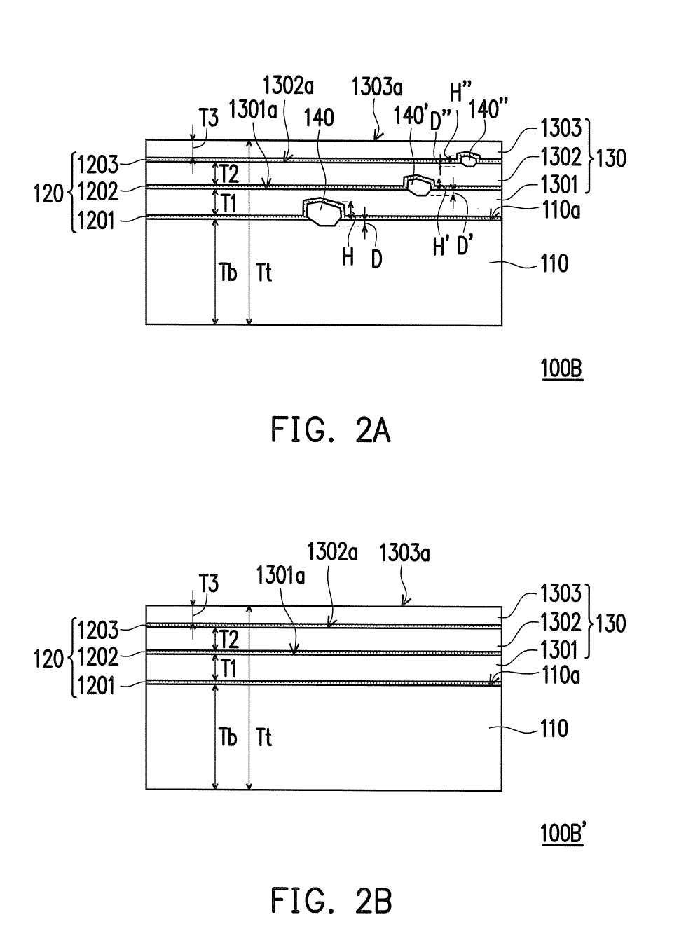

FIG. 2A is a cross-sectional view of a substrate structure according to the second embodiment of the disclosure. A structure and a fabricating method in the embodiment of FIG. 2A are similar to that in the embodiment of FIG. 1A to FIG. 1D, thus identical or similar elements are indicated by identical or similar reference numbers, and the descriptions thereof are not repeated. Referring to FIG. 2A, a difference between the embodiment of FIG. 2A and the embodiment of FIG. 1A to FIG. 1D is that, a substrate structure 100B further includes at least one protruding object 140″, a third inorganic layer 1203 and a third organic layer 1303. The at least one protruding object 140″ is disposed on the upper surface 1302a of the second organic layer 1302. A material of the protruding object 140″ may be identical to that of the second organic layer 1302, and may also be different from that of the second organic layer 1302. Further, in the present embodiment, a maximum height of the protruding object 140″ protruded from the upper surface 1302a of the second organic layer 1302 is H″, and a maximum depth of the protruding object 140″ embedded in the second organic layer 1302 is D″, wherein D″≧(1/4)(H″+D″), for example. The third inorganic layer 1203 covers the upper surface 1302a of the second organic layer 1302 and a partial surface of the protruding object 140″ protruded from the upper surface 1302a, and the third organic layer 1303 covers the third inorganic layer 1203 and the protruding object 140″. In an embodiment, a material of the bottom organic layer 110 may be identical to a material of at least one of the first organic layer 1301, the second organic layer 1302 and the third organic layer 1303. In the present embodiment, a thickness of the third organic layer 1303 is T3, wherein T3≧1.1 H″. In addition, the thickness T3 of the third organic layer 1303 may also be set to T1≧T2≧T3, but the disclosure is not limited thereto. In other embodiments, it may also be T1≧T3≧T2, T2≧T1≧T3, T2≧T3≧T1, T3≧T1≧T2 or T3≧T2≧T1 as long as the upper surface (the upper surface 1303a) of the substrate structure 100B may be smooth.

FIG. 2B is a cross-sectional view of a substrate structure according to the third embodiment of the disclosure. A structure and a fabricating method in the embodiment of FIG. 2B are similar to that in the embodiment of FIG. 2A, thus identical or similar elements are indicated by identical or similar reference numbers, and the descriptions thereof are not repeated. Referring to FIG. 2B, a difference between the embodiment of FIG. 2B and the embodiment of FIG. 2A is that, a substrate structure 100 does not include the protruding objects 140, 140′ and 140″. In the present embodiment, the thicknesses of the organic layers 130 (including the first organic layer 1301, the second organic layer 1302 and the third organic layer 1303) may be set to T1≧T2≧T3. Therefore, on the direction from where adjacent to the bottom organic layer 110 to where far from the bottom organic layer 110, as the thicknesses of the organic layers 130 being gradually reduced, demands for the gas barrier capability in the inorganic layer 120 far from the bottom organic layer 110 may be reduced.

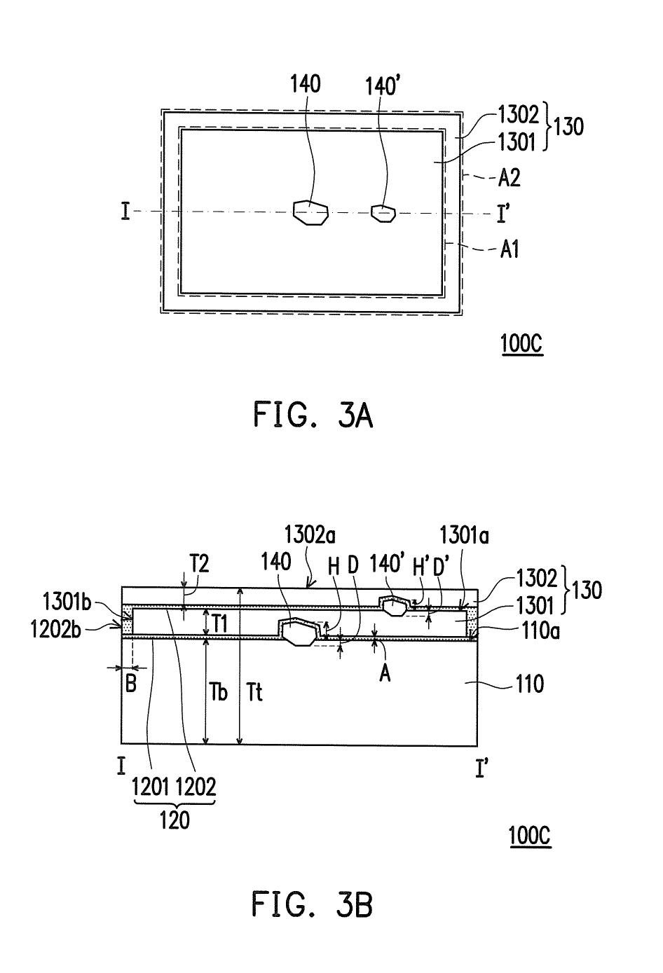

FIG. 3A is a top view of a substrate structure according to the fourth embodiment of the disclosure, and FIG. 3B is a cross-sectional view along line I-I′ in FIG. 3A. A structure and a fabricating method in the embodiment of FIG. 3A to FIG. 3B are similar to that in the embodiment of FIG. 1A to FIG. 1D, thus identical or similar elements are indicated by identical or similar reference numbers, and the descriptions thereof are not repeated. Referring to FIG. 3A to FIG. 3B, a difference between the embodiment of FIG. 3A to FIG. 3B and the embodiment of FIG. 1A to FIG. 1D is that, in a substrate structure 100C, an area A1 of the first organic layer 1301 is less than an area A2 of the second organic layer 1302, but the disclosure is not limited thereto. In other embodiments, the area A1 may be equal to or greater than the area A2.

The second inorganic layer 1202 covers the upper surface 1301a and a sidewall 1301b of the first organic layer 1301. In the present embodiment, a distance between a sidewall 1202b of the second inorganic layer 1202 and the sidewall 1301b of the first organic layer 1301 is B, a thickness of the first inorganic layer 1201 is A, and the distance B is greater than the thickness A. Therefore, the sidewall 1301b of the first organic layer 1301 is under protection of the inorganic layer 1202, so as to avoid moisture and oxygen laterally permeating into the first organic layer 1301, thereby improving a lateral gas barrier capability of the first organic layer 1301. However, the disclosure is not limited thereto. In other embodiments, the distance B may also be equal to or less than the thickness A.

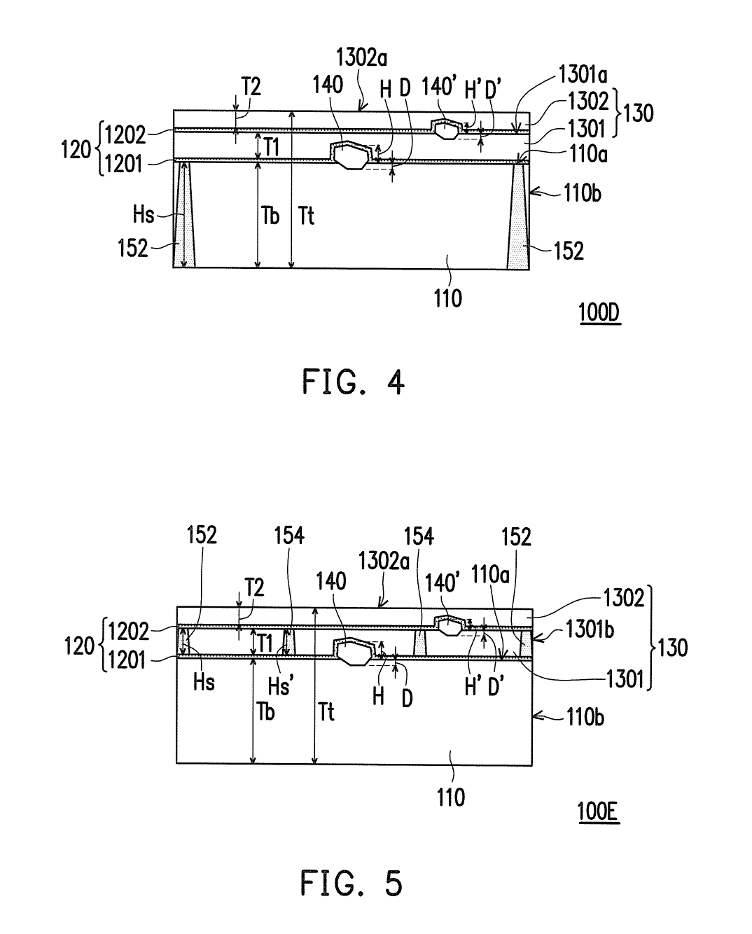

FIG. 4 to FIG. 8 are cross-sectional views of substrate structures according to fifth to ninth embodiments of the disclosure. Structures and fabricating methods in the embodiments of FIG. 4 to FIG. 8 are similar to that in the embodiment of FIG. 1A to FIG. 1D, thus identical or similar elements are indicated by identical or similar reference numbers, and the descriptions thereof are not repeated. A difference between the embodiments of FIG. 4 to FIG. 8 and the embodiment of FIG. 1A to FIG. 1D is that, the substrate structure further includes a plurality of spacers. The spacers may be disposed in the bottom organic layer 110 or the organic layers 130, or disposed on an upper surface of the substrate structure, which are described in detail as follows.

Referring to FIG. 4, in a substrate structure 100D, at least one first spacer 152 is disposed in the bottom organic layer 110, and a height Hs of the first spacer 152 is equivalent to the thickness Tb of the bottom organic layer 110. In the present embodiment, the first spacer 152 is disposed adjacent to a sidewall 110b of the bottom organic layer 110, wherein the first spacer 152 in the top view may be a continuous and enclosed ring structure, or a discontinuous section structure surrounding around the sidewall 110b of the bottom organic layer 110. Therefore, the sidewall 110b of the bottom organic layer 110 is configured with the first spacer 152, so as to avoid moisture and oxygen laterally permeating to the first organic layer 110, thereby improving the lateral gas barrier capability of the bottom organic layer 110. However, the disclosure is not limited thereto. In other embodiments, a cross-section of the first spacer 152 may be a rectangle, a trapezoid or other suitable shapes as long as moisture and oxygen may be avoided laterally permeating to the first organic layer 110.

A material of the first spacer 152 includes an inorganic material, an organic material, a metal composite material, a non-metal composite material, a metal material or a combination thereof. The inorganic material is, for example, silicon dioxide, silicon nitride or silicon oxynitride. The organic material is, for example, a photoresist. The metal composite material is, for example, a silver-containing composite material, an aluminum-containing composite material or other metal composite materials. A method of forming the first spacer 152 includes, for example, a spray, a screen print, a photolithography, a low-temperature sintering or other suitable methods. For instance, before the step of FIG. 1 A is adopted to fabricate the bottom organic layer 110, one of above-said methods may be adopted to fabricate the first spacer 152 on the carrier 102 (illustrated in FIG. 1A).

Referring to FIG. 5, in a substrate structure 100E, the at least one first spacer 152 is disposed in the first organic layer 1301, and the height Hs of the first spacer 152 is equivalent to the thickness T1 of the first organic layer 1301. Furthermore, at least one second spacer 154 is disposed in the first organic layer 1301, and a height Hs′ of the second spacer 154 is equivalent to the thickness T1 of the first organic layer 1301. In the present embodiment, the first spacer 152 is disposed adjacent to the sidewall 1301b of the first organic layer 1301. Therefore, the sidewall 1301b of the first organic layer 1301 is configured with the first spacer 152, so as to avoid moisture and oxygen laterally permeating to the first organic layer 1301, thereby improving the lateral gas barrier capability of the first organic layer 1301. Furthermore, the second spacer 154 may be disposed at any position in the first organic layer 1301 or may be any suitable shapes as long as the thickness T1 of the first organic layer 1301 may be maintained. However, the disclosure is not limited thereto. In other embodiments, the first organic layer 1301 may include only the first spacer 152 or only the second spacer 154, and cross-sections of the first spacer 152 or the second spacer 154 may be a rectangle, a trapezoid or other suitable shapes. In addition, the first spacer 152 or the second spacer 154 may be disposed in the second organic layer 1302 or other organic layers (not illustrated). The first spacer 152 or the second spacer 154 in the top view may be a continuous and enclosed ring structure or a discontinuous section structure, distributed in the first organic layer 1301, the second organic layer 1302, or other organic layers (not illustrated).

A method of forming the first spacer 152 and the second spacer 154 includes, for example, a spray, a screen print, a photolithography, a low-temperature sintering or other suitable methods. Materials of the first spacer 152 and the second spacer 154 may include an inorganic material, an organic material, a metal composite material, a non-metal composite material, a metal material or a combination thereof. The inorganic material is, for example, silicon dioxide, silicon nitride or silicon oxynitride. The organic material is, for example, a photoresist. The metal composite material is, for example, a silver-containing composite material, an aluminum-containing composite material or other metal composite materials. In case the materials of the first spacer 152 or the second spacer 154 are metal material, the fabricating method of the first spacer 152 or the second spacer 154 may be a sintering process, but the disclosure is not limited thereto.

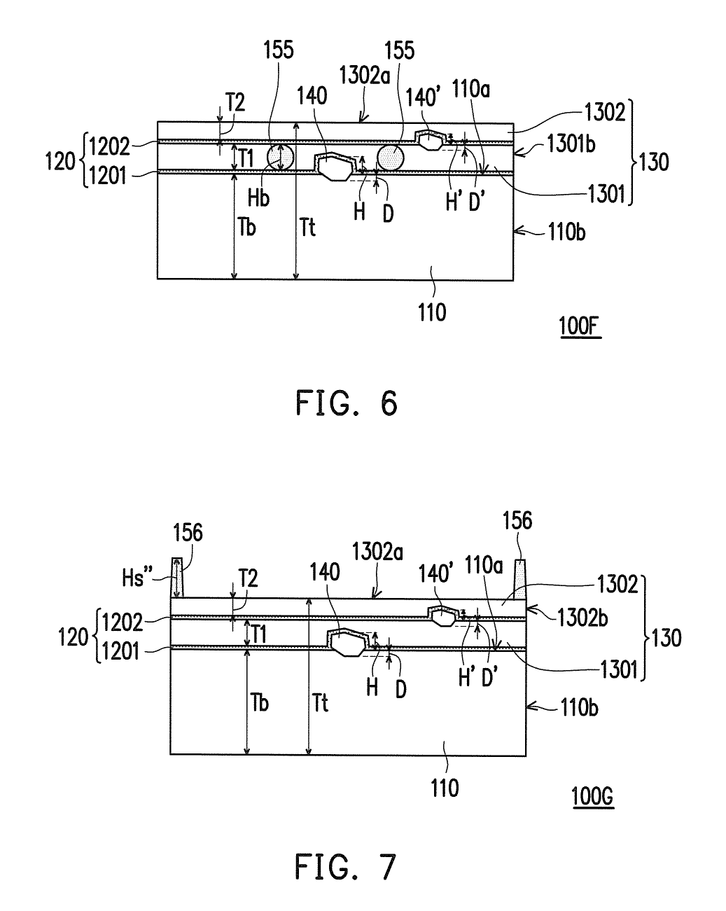

Referring to FIG. 6, in a substrate structure 100F, a plurality of third spacers 155 are, for example, disposed in the first organic layer 1301, and heights Hb of the third spacers 155 are equal to or less than the thickness T1 of the first organic layer 1301. The third spacers 155 may be disposed at any positions in the first organic layer 1301 or may have any suitable shape. The third spacers 155 may be used to maintain a shape of the substrate while being bent. The material of the organic layer 130 is bend-able, while being bent, the thickness at a bending portion is thinner and the thickness at a non-bending portion is relatively thicker. This variation of the thickness may cause malfunctions to the devices on the substrate. Therefore, by adding a hard spacer with rigidity to the organic layer 130, excessive variation of the thickness may be avoid while bending the substrate. However, the disclosure is not limited thereto. In other embodiments, a cross-section of each of the third spacers 155 may be a circle, an oval or other suitable shapes. In addition, the third spacers 155 may also be disposed in the second organic layer 1302 or other organic layers (not illustrated). A material of the third spacers 155 includes an inorganic material, an organic material, a metal material or a combination thereof. The inorganic material is, for example, a glass powder or ceramic powder. The organic material is, for example, a thermosetting photoresist. The metal material is, for example, a silver powder, an aluminum powder, a plumbum powder, a stainless steel powder, or other metal powders.

Referring to FIG. 7, in a substrate structure 100G, at least one fourth spacer 156 is disposed on an upper surface (the upper surface 1302a of the second organic layer 1302) of the substrate structure 100G, and a height of the fourth spacer 156 is Hs″. In the present embodiment, the fourth spacer 156 is disposed at a sidewall 1302b of the second organic layer 1302, wherein the fourth spacer 156 in the top view may be a continuous and enclosed ring structure, or a discontinuous section structure surrounding the sidewall 1302b of the second organic layer 1302. When the substrate structure 100G composes a package substrate together with an opposite substrate (not illustrated), the height Hs″ is equivalent to a height of an inner space of said package structure, so as to improve the lateral gas barrier capability of the inner space of said package structure. However, the disclosure is not limited thereto. In other embodiments, a cross-section of the fourth spacer 156 may be a rectangle, a trapezoid or other suitable shapes as long as the laterally permeating of moisture and oxygen into the inner space of the package structure may be avoided. A method of forming the fourth spacer 156 includes, for example, a spray, a screen print, a photolithography, a low-temperature sintering or other suitable methods. A material of the fourth spacer 156 includes an inorganic material, an organic material, a metal composite material, a non-metal composite material, a metal material or a combination thereof. The inorganic material is, for example, silicon dioxide, silicon nitride or silicon oxynitride. The organic material is, for example, a photoresist. The metal composite material is, for example, a silver-containing composite material, an aluminum-containing composite material or other metal composite materials.

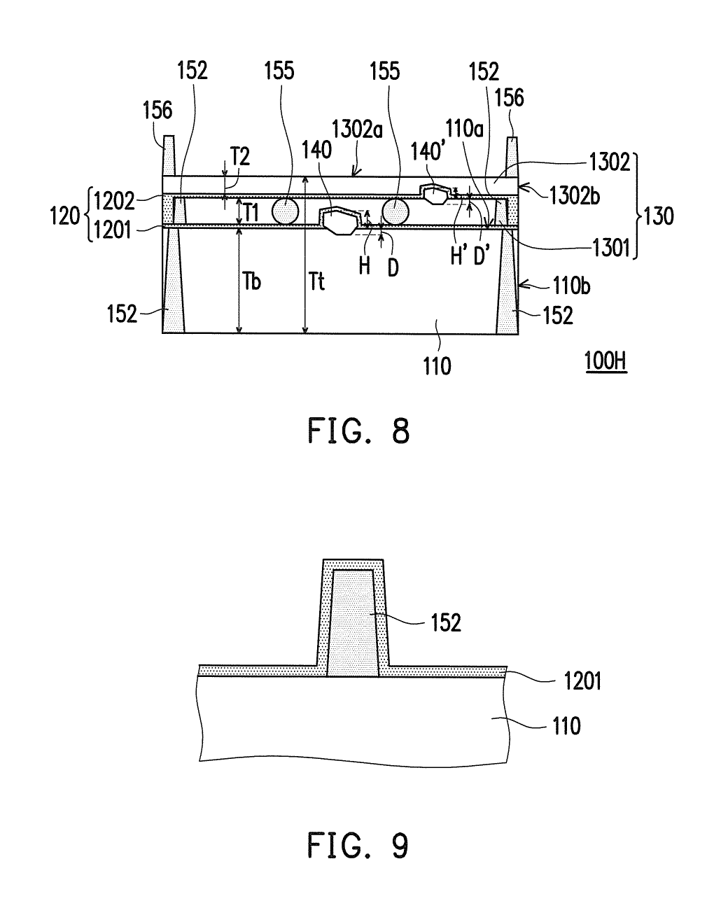

Referring to FIG. 8, in a substrate structure 100H, the at least one first spacer 152 is disposed in the bottom organic layer 110, the first spacer 152 and the third spacers 155 are disposed in the first organic layer 1301, and the fourth spacer 156 is disposed on an upper surface (the upper surface 1302a of the second organic layer 1302) of the substrate structure 100H. Therein, shapes of the first spacer 152, the third spacers 155 and the fourth spacer 156 may be different from one another. However, the disclosure is not limited thereto. In other embodiments, dispositions of the spacers may also any combination from the embodiments of FIG. 4 to FIG. 8.

In addition, as shown in FIG. 9, in case the material of the first spacer 152 is the organic material, the inorganic layer 120 (the first inorganic material 1201) may selectively covers the first spacer 152. Therefore, the first spacer may be disposed between the first inorganic layer 1201 and the bottom organic layer 110, and the first inorganic layer 1201 may disposed along a contour outline of the first spacer 152.

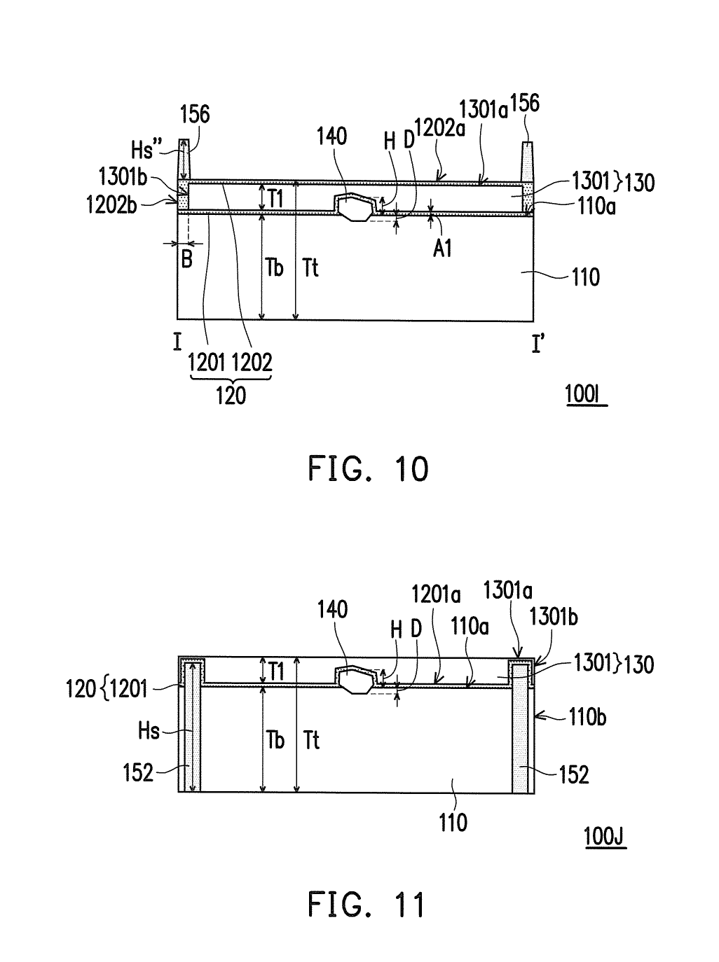

FIG. 10 is a cross-sectional view of a substrate structure according to the tenth embodiment of the disclosure. A structure and a fabricating method in the embodiment of FIG. 10 are similar to that in the embodiment of FIG. 1 A to FIG. 1D, thus identical or similar elements are indicated by identical or similar reference numbers, and the descriptions thereof are not repeated. Referring to FIG. 10, a difference between the embodiment of FIG. 10 and the embodiment of FIG. 1A to FIG. 1D is that, in a substrate structure 100I, the area A1 of the first organic layer 1301 is less than an area of the bottom organic layer 110, but the disclosure is not limited thereto. In other embodiments, the area A1 may also be equal to or greater than the area of the bottom organic layer 110. Further, the substrate structure 100I further includes the at least one fourth spacer 156.

The second inorganic layer 1202 covers the upper surface 1301a and a sidewall 1301b of the first organic layer 1301. In the present embodiment, a distance between a sidewall 1202b of the second inorganic layer 1202 and the sidewall 1301b of the first organic layer 1301 is B, a thickness of the first inorganic layer 1201 is A, and the distance B is greater than the thickness A. Therefore, the sidewall 1301b of the first organic layer 1301 is configured with the inorganic layer 1202, so as to avoid moisture and oxygen laterally permeating to the first organic layer 1301, thereby improving a lateral gas barrier capability of the first organic layer 1301. However, the disclosure is not limited thereto. In other embodiments, the distance B may be equal to or less than the thickness A.

The at least one fourth spacer 156 is disposed on an upper surface (an upper surface 1202a of the second inorganic layer 1202) of the substrate structure 100G, and the height of the fourth spacer 156 is Hs″. In the present embodiment, the fourth spacer 156 is disposed around the sidewall 1202b of the second inorganic layer 1202, wherein the fourth spacer 156 in the top view may be a continuous and enclosed ring structure, or a discontinuous section structure surrounding the sidewall 1202b of the second inorganic layer 1202. When the substrate structure 100I composes a package substrate together with an opposite substrate (not illustrated), the height Hs″ is equivalent to the height of an inner space of said package structure, so as to improve the lateral gas barrier capability of the inner space of said package structure.

In the embodiments of FIG. 4, FIG. 5 and FIG. 8, the first spacer 152 is illustrated as being disposed in the bottom organic layer 110 or the first organic layer 1301 (i.e., the height Hs of the first spacer 152 is equivalent to the thickness Tb of the bottom organic layer 110 or the thickness T1 of the first organic layer 1301) as examples, but the disclosure is not limited thereto. In other embodiments, the first spacer 152 may penetrate through at least one organic layer. In other words, the height Hs of the first spacer 152 may be greater than the thickness Tb of the bottom organic layer 110 or the thickness T1 of the first organic layer 1301.

FIG. 11 is a cross-sectional view of a substrate structure according to the eleventh embodiment of the disclosure. A structure and a fabricating method in the embodiment of FIG. 11 are similar to that in the embodiment of FIG. 4, thus identical or similar elements are indicated by identical or similar reference numbers, and the descriptions thereof are not repeated. A difference between the embodiment of FIG. 11 and the embodiment of FIG. 4 is that, in a substrate structure 100J, the at least one first spacer 152 is protruded from the upper surface 110a of the bottom organic layer 110, and the height Hs of the first spacer 152 is greater than the thickness Tb of the bottom organic layer 110. Further, the first inorganic layer 1201 covers the bottom organic layer 110, the protruding object 140, and a partial surface of the first spacer 152 protruded from the upper surface 110. The first organic layer 1301 is formed on the first inorganic layer 1201.

In the present embodiment, the first spacer 152 is disposed adjacent to the sidewall 110b adjacent to the bottom organic layer 110 and protruded from the upper surface 110a of the bottom organic layer 110. Therefore, the sidewall 110b of the bottom organic layer 110 and the sidewall 1301b of the first organic layer 1301 are configured with the first spacer 152, so as to avoid moisture and oxygen laterally permeating to the bottom organic layer 110 and the first organic layer 1301, thereby improving the lateral gas barrier capabilities of the bottom organic layer 110 and the first organic layer 1301. However, the disclosure is not limited thereto. In other embodiments, a cross-section of the first spacer 152 may be a rectangle, a trapezoid or other suitable shapes as long as moisture and oxygen may be avoided laterally permeating to the bottom organic layer 110 the first organic layer 1301.

FIG. 12 is a cross-sectional view of a substrate structure according to the twelfth embodiment of the disclosure. A structure and a fabricating method in the embodiment of FIG. 12 are similar to that in the embodiment of FIG. 11, thus identical or similar elements are indicated by identical or similar reference numbers, and the descriptions thereof are not repeated. A difference between the embodiment of FIG. 12 and the embodiment of FIG. 11 is that, a substrate structure 100K further includes the second inorganic layer 1202. The second inorganic layer 1202 covers the upper surface 1301a of the first organic layer 1301. In the substrate structure 100K, the at least one first spacer 152 is protruded from the upper surface 110a of the bottom organic layer 110, and the height Hs of the first spacer 152 is greater than the thickness Tb of the bottom organic layer 110. Further, the first inorganic layer 1201 covers the bottom organic layer 110, the protruding object 140, and a partial surface of the first spacer 152 protruded from the upper surface 110. The first organic layer 1301 is formed on the first inorganic layer 1201. The second inorganic layer 1202 covers the upper surface 1301a of the first organic layer 1301, and the second inorganic layer 1202 has the smooth upper surface 1202a. However, the disclosure is not limited thereto. In other embodiments (not illustrated), the at least one first spacer 152 may be protruded from the upper surface 1301a of the first organic layer 1301, and the height Hs of the first spacer 152 may be greater than the thickness T1 of the first organic layer 1301. Further, the second inorganic layer 1202 covers the first organic layer 1301 and a partial surface of the first spacer 152 protruded from the upper surface 1301a.

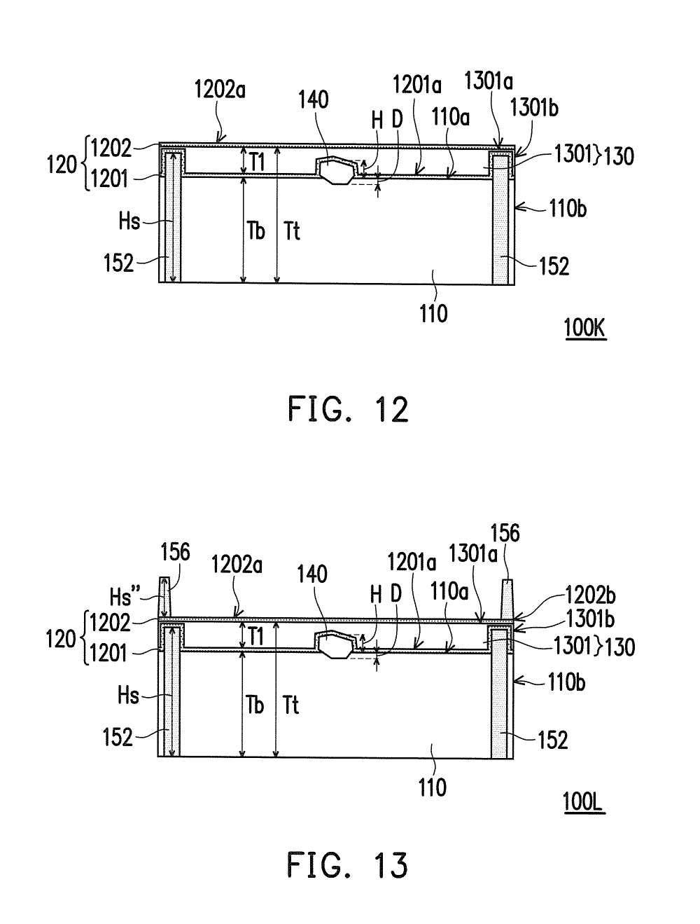

FIG. 13 is a cross-sectional view of a substrate structure according to the thirteenth embodiment of the disclosure. A structure and a fabricating method in the embodiment of FIG. 13 are similar to that in the embodiment of FIG. 12, thus identical or similar elements are indicated by identical or similar reference numbers, and the descriptions thereof are not repeated. A difference between the embodiment of FIG. 13 and the embodiment of FIG. 12 is that, a substrate structure 100L further includes the at least one fourth spacer 156. The fourth spacer 156 is disposed on an upper surface (the upper surface 1202a of the second inorganic layer 1202) of the substrate structure 100L, and a height of the fourth spacer 156 is Hs″. In the present embodiment, the fourth spacer 156 is disposed adjacent to the sidewall 1202b of the second inorganic layer 1202, wherein the fourth spacer 156 in the top view may be a continuous and enclosed ring structure, or a discontinuous section structure surrounding the sidewall 1202b of the second inorganic layer 1202. When the substrate structure 100L composes a package substrate together with an opposite substrate (not illustrated), the height Hs″ is equivalent to a height of an inner space of said package structure, so as to improve the lateral gas barrier capability of the inner space of said package structure.

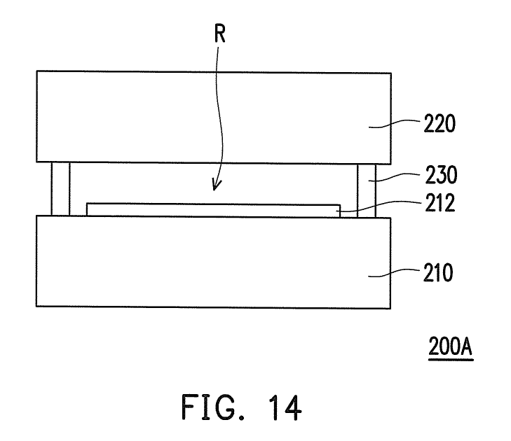

FIG. 14 is a cross-sectional view of a package structure according to an embodiment of the disclosure. Referring to FIG. 14, a package structure 200A is, for example, a package structure of an organic light emitting device (OLED) or other suitable devices. Hereinafter, the package structure 200A is illustrated by using the organic light emitting device as an example. The package structure 200A at least includes a first substrate 210, an organic light emitting device 212 and a second substrate 220.

The first substrate 210 is disposed opposite to the second substrate 220. At least one of the first substrate 210 and the second substrate 220 can have the design selected from at least one of aforesaid substrate structures 110A to 100L.

The organic light emitting device 212 is disposed between the first substrate 210 and the second substrate 220. In the present embodiment, the organic light emitting device 212 is, for example, disposed on the first substrate 210, but the disclosure is not limited thereto. In the other embodiments, the organic light emitting device 212 may be disposed at any position in an inner space R of the package structure 200A. The organic light emitting device 212 is, for example, an active organic light emitting device or a passive organic light emitting device. Therein, the active organic light emitting device or the passive organic light emitting device may also be further classified into a bottom-emitting organic light emitting device or a top-emitting organic light emitting device, and the organic light emitting device 212 may be a display or a plane light source.

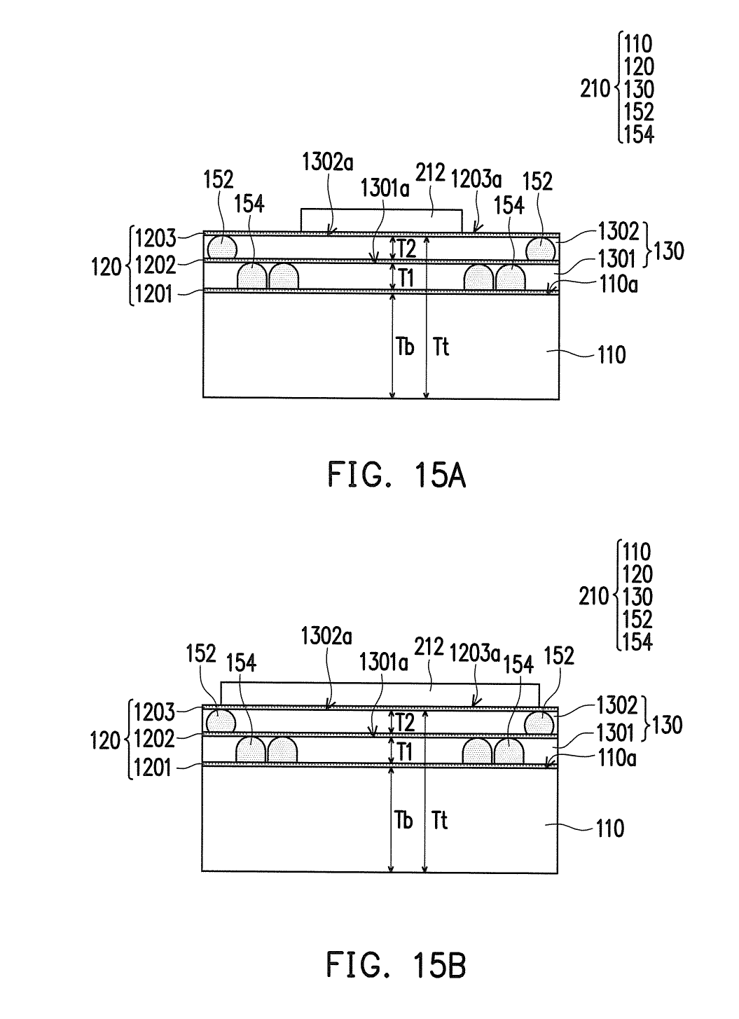

For instance, as shown in FIG. 15A and FIG. 15B, the first substrate 10 includes, for example, the bottom organic layer 110, the inorganic layers 120, the organic layers 130, the at least one first spacer 152 and the at least one second spacer 154, and the organic light emitting device 212 is, for example, disposed on an upper surface 1203a of the third inorganic layer 1203 of the first substrate 210. As shown in FIG. 15A, in case the organic light emitting device 212 is the bottom-emitting organic light emitting device, the organic light emitting device 212 is disposed not overlapping with the first spacer 152 or the second spacer 154 (the first spacer 152 or the second spacer 154 may be disposed surrounding periphery of the organic light emitting device 212), so as to avoid a light beam emitted from the organic light emitting device 212 being blocked by the spacers. As shown in FIG. 15B, in case the organic light emitting device 212 is the top-emitting organic light emitting device, the organic light emitting device 212 may be disposed overlapping with the first spacer 152 or the second spacer 154 (the organic light emitting device 212 may be disposed on places within a range where the first spacer 152 and the second spacer 154 are provided). However, the disclosure is not limited thereto. In other embodiments, dispositions of the spacers may any combination from the embodiments of FIG. 4 to FIG. 13.

Referring to FIG. 14, in the present embodiment, the package structure 200A further includes, for example, a seal 230. The seal 230 is disposed between the first substrate 210 and the second substrate 220. The first substrate 210 and the second substrate 220 may be bonded through the seal 230. In other embodiments, the seal 230 may also be replaced by a frit (such as a glass frit) other suitable adhesion layers, or a combination thereof. In addition, by using the substrate structure 100G of FIG. 7, the substrate structure 100H of FIG. 8, the substrate structure 100I of FIG. 10 or the substrate structure 100L of FIG. 13 as the first substrate 210, the fourth spacer 156 may facilitate in improving the lateral gas barrier capability of the package structure 200A. However, the disclosure is not limited thereto. In other embodiments, the fourth spacer 156 in the top view may be a continuous and enclosed ring structure, or a discontinuous section structure. The fourth spacer 156 may be disposed between the first substrate 210 and the second substrate 220, and the fourth spacer 156 on the first substrate 210 may then be bonded to the second substrate 220 through an adhesion layer as a replacement of the seal 230 (not illustrated).

In the embodiment of FIG. 14, it is illustrated by using the package structure 200A which further includes the seal 230 as an example, but the disclosure is not limited thereto. In other embodiments, the package structure may also be other suitable package structures.

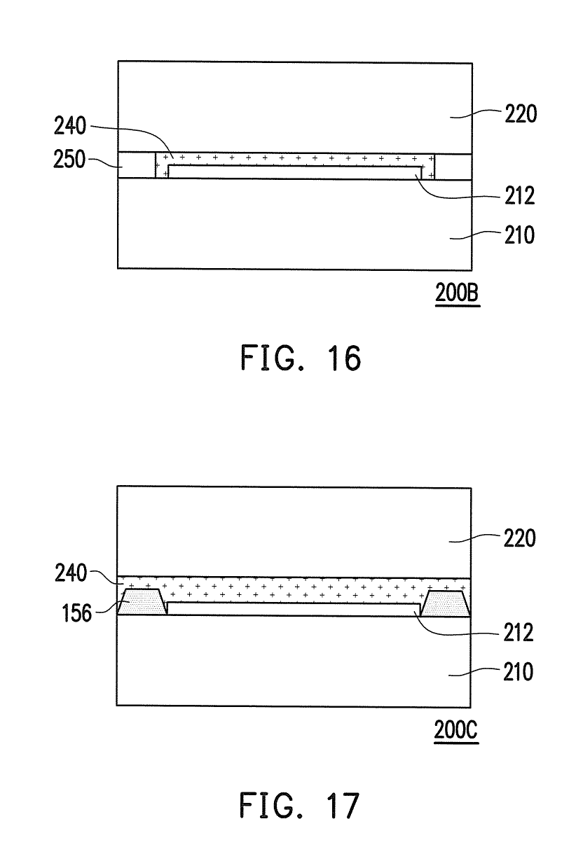

FIG. 16 to FIG. 19 are cross-sectional views of package structures according to other embodiments of the disclosure. Structures of the embodiments depicted in FIG. 16 to FIG. 19 are similar to the structure of the embodiment of FIG. 14, thus identical or similar elements are indicated by identical or similar reference numbers, and the descriptions thereof are not repeated. A difference between the embodiments of FIG. 16 to FIG. 19 and the embodiment of FIG. 14 is that the package structures are different.

Referring to FIG. 16, a package structure 200B includes the first substrate 210, the organic light emitting device 212, the second substrate 220, a protective layer 240 and an adhesive material 250. The protective layer 240 covers the first substrate 210 and the organic light emitting device 212, and the protective layer 240 is disposed between the first substrate 210 and the second substrate 220. A material of the protective layer 240 is, for example, an inorganic material, an organic material or other suitable materials. The inorganic material includes, for example, silicon oxide, silicon nitride, silicon oxynitride, an aluminum oxide, an aluminum or other suitable inorganic gas barrier materials. The adhesive material 250 is disposed between the first substrate 210 and the second substrate 220, so that the first substrate 210 and the second substrate 220 may be bonded through the adhesive material 250. In other embodiments, the adhesive material 250 may be replaced by a frit (such as a glass frit) other suitable adhesion layers, or a combination thereof.

Referring to FIG. 17, a package structure 200C includes the first substrate 210, the organic light emitting device 212, the second substrate 220, the at least one fourth spacer 156 and the protective layer 240. For example, by using the substrate structure 100G of FIG. 7, the substrate structure 100H of FIG. 8, the substrate structure 100I of FIG. 10 or the substrate structure 100L of FIG. 13 as the first substrate 210, the fourth spacer 156 may facilitate in improving the lateral gas barrier capability of the package structure 200C. However, the disclosure is not limited thereto. In other embodiments, the fourth spacer 156 may be a continuous and enclosed ring structure, or a discontinuous section structure. Further, the protective layer 240 covers the first substrate 210, the organic light emitting device 212 and the fourth spacer 156, and the protective layer 240 is disposed between the first substrate 210 and the second substrate 220. Moreover, in the present embodiment, the adhesion layer (not illustrated) may be used to bond the first substrate 210 to the second substrate 220.

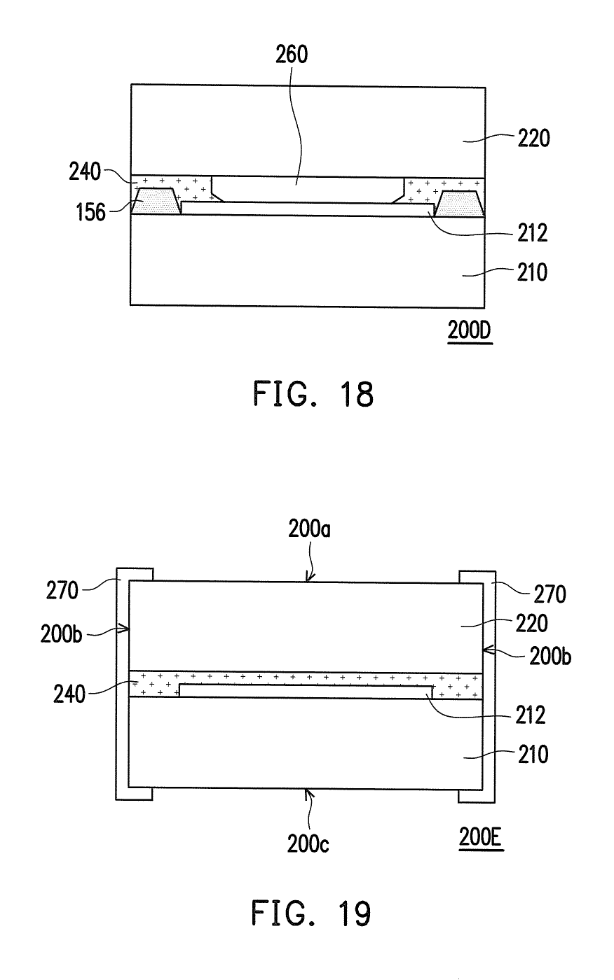

Referring to FIG. 18, a difference between a package structure 200D and the package structure 200C is that, the package structure 200D further includes a getter 260. The getter 260 is disposed between the first substrate 210 and the second substrate 220. The getter 260 is utilized to maintain a vacuum status within a device and to absorb parts of gas molecules. The getter 260 may include a non-evaporable getter, an evaporable getter, or a combination thereof.

Referring to FIG. 19, a package structure 200E includes the first substrate 210, the organic light emitting device 212, the second substrate 220, the protective layer 240 and a gas barrier 270. The protective layer 240 covers the first substrate 210 and the organic light emitting device 212, and the protective layer 240 is disposed between the first substrate 210 and the second substrate 220. The gas barrier 270 covers a part of an upper surface 200a, the entire lateral side 200b and a part of a lower surface 200c of the package structure 200a. The gas barrier 270 is, for example, a metal foil, a plastic gas barrier or other suitable attaching (wrapping) gas barriers. Moreover, in the present embodiment, the adhesion layer (not illustrated) may be used to bond the first substrate 210 to the second substrate 220.

In the present embodiment, a gas barrier substrate (ex. the substrate structures 100A to 100L) with favorable gas barrier capability is adopted to package the organic light emitting device 212. The permeation of moisture and oxygen may be blocked, so as to solve the problem in which lifespan is shorten due to deterioration of the organic light emitting device 212. The organic light emitting device 212 is capable of providing a favorable reliability.

In the substrate structure according to an embodiment of the disclosure, T (the thickness of each organic layer)≧1.1 H (the height of the protruding object on the previous organic layer), or T1(the thickness of the previous organic layer)≧T2 (the thickness of each organic layer). Therefore, the thickness of each organic layer is capable of covering and smoothing the protruding object on the previous organic layer, so that the upper surface of the substrate structure may be smoother to improve the gas barrier (including moisture and oxygen) capability of the substrate structure. In an embodiment, the organic layers may adopt the material with better resistance to high temperature. The organic layers with better resistance to high temperature may include the smoother upper surface (since the bubbles are not formed) to solve problems including non-uniform thickness, uneven surface and discontinuous film (such as disconnection) for the inorganic layers formed thereon, such that the substrate structure may provide the gas barrier characteristic and the flexibility characteristic being more preferable.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A substrate structure, comprising:
a bottom organic layer;
a plurality of inorganic layers comprising a bottom inorganic layer and an upper inorganic layer;
at least one organic layer, disposed between the bottom inorganic layer and the upper inorganic layer; and
a protruding object, protruded from an upper surface of the bottom organic layer, wherein the bottom inorganic layer conformally covers the protruding object, a maximum height of the protruding object protruded from the upper surface of the bottom organic layer is H, and a distance measured from the bottom inorganic layer at the maximum height of the protruding object to a bottom of the upper inorganic layer is ≧0.1 H.

2. The substrate structure of claim 1, wherein at least one of the bottom organic layer and the organic layer is made of a material, in which 5% weight loss temperature is greater than 400° C. and an amount of an outgas at 400° C. is less than 50 ng/cm².

3. The substrate structure of claim 2, wherein the material of the at least one of the bottom organic layer and the organic layer is polyimide.

4. The substrate structure of claim 1, wherein the substrate structure comprises a plurality of organic layers and areas of at least two of the organic layers are different.

5. The substrate structure of claim 4, wherein thicknesses of the organic layers are gradually reduced outwardly from the bottom organic layer.

6. The substrate structure of claim 1, wherein a total thickness of the substrate structure is 5 μm to 50 μm.

7. The substrate structure of claim 1, further comprising at least one spacer, disposed in at least one of the bottom organic layer and the organic layer, adjacent to at a sidewall of the at least one of the bottom organic layer and the organic layer.

8. The substrate structure of claim 7, wherein a height of the spacer is equivalent to a thickness of the at least one of the bottom organic layer and the organic layer.

9. The substrate structure of claim 7, wherein the spacer is disposed in the bottom organic layer, protruded from an upper surface of the bottom organic layer, and a protruding height of the spacer from the upper surface of the bottom organic layer is greater than H.

10. The substrate structure of claim 9, wherein the bottom inorganic layer covers the bottom organic layer, the protruding object, and a partial surface of the spacer protruded from the upper surface of the bottom organic layer.

11. The substrate structure of claim 1, wherein a buried depth of the protruding object buried in the bottom organic layer is D, wherein D≧(1/4)(H+D).

12. The substrate structure of claim 1, wherein a material of the bottom organic layer is identical to a material of the organic layer.

13. The substrate structure of claim 1, wherein a material of the protruding object is identical with a material of the bottom organic layer or the organic layer.

14. The substrate structure of claim 1, wherein a material of at least one of the bottom organic layer and the at least one organic layer comprises polyimide (PI), polycarbonate (PC), polyethersulfone (PES), polynorbornene (PNB), polyetherimide (PEI), polyethylene terephthalate (PEN), polyethylene terephthalate (PET), polymethylmethacrylate (PMMA), polytetrafluoroethene (PTFE), parylene series material, perfluorinated chemicals (PFCs), or a combination thereof.

15. The substrate structure of claim 1, further comprising another protruding object protruded from an upper surface of the organic layer.

16. The substrate structure of claim 15, wherein the another protruding object is covered by the upper inorganic layer.

17. The substrate structure of claim 15, wherein a size of the another protruding object is smaller than a size of the at least one protruding object.

18. The substrate structure of claim 15, wherein a maximum height of the another protruding object protruded from the upper surface of the organic layer is H′, a buried depth of the another protruding object buried in the organic layer is D′, and D′≧(1/4)(H′+D′).

19. The substrate structure of claim 15, wherein a material of the another protruding object is identical with a material of the organic layer or the bottom organic layer.

20. The substrate structure of claim 1, wherein the upper inorganic layer comprises a sidewall extending toward the bottom inorganic layer and covering along a sidewall of the organic layer.
